(19) United States
(12) Patent Application Publication
(10) Pub. No.: US 2013/0113473 A1
(43) Pub. Date: May 9, 2013

(54) MAGNETIC SENSOR WITH SHUNTING LAYERS AND MANUFACTURING METHOD THEREOF

(71) Applicant: Wei XIONG, Santa Clara, CA (US)

(72) Inventor: Wei XIONG, Santa Clara, CA (US)

(73) Assignee: SAE Magnetics (H.K.), Hong Kong (CN)

(21) Appl. No.: 13/289,539

(22) Filed: Nov. 4, 2011

(51) Int. Cl. G01R 33/02; H05K 3/10

(52) U.S. Cl. 324/244; 29/846

(57) ABSTRACT

The present invention directs a magnetic sensor with shunting layers, and the magnetic sensor includes a magnetic sensor bar which having an integral structure; and a plurality of shunting layers whose resistivity is lower than the magnetic sensor bar, respectively forming on the magnetic sensor bar in length direction without any physical separation therebetween, with spaces between every two adjacent shunting layers; and two electrode pads respectively forming on two ends of the magnetic sensor bar. The present invention also provides manufacturing method of the magnetic sensor.

### FIELD OF THE INVENTION

The present invention relates to sensor technology field, and more particularly, to a magnetic sensor with shunting layers and a manufacturing method thereof.

### BACKGROUND OF THE INVENTION

Sensor is a physical device, which could detect and sense the external signal and the physical conditions (such as light, heat, humidity) and/or chemical composition (such as smoke), and will transfer the information into electrical signal for transmitting to other devices. Magnetic sensor is one kind of the sensor. The magnetic sensor serves the function of changing the magnetic performance of the sensitive element induced by magnetic field, current, stress-strain, temperature and light change, etc into electrical signal, so as to measure the related physical quantity, especially the tiny physical quantity of the device. Since the magnetic sensor is characteristic by its high sensitivity in comparison to other type of sensors, it is widely used in the field of aerospace, geological exploration, medical imaging, and information acquisition and so on. As the progress of technology and the magnetic sensor is advantage with its low power consumption, small volume, high sensitivity, easy integrated, low cost, fast response, high resolution, high stability, high reliability, the magnetic sensor is a core portion of the magnetic sensor device.

In certain magnetic sensing applications, there is a need to use long stripes of magnetic sensor element to match the spatially distributed magnetic signals. Long stripe is also essential to achieve large sensor resistance and low power consumption. Long magnetic stripes tend to have larger magnetic coercive force due to the difference in the demagnetization factors between the long axis and short axis directions, and bring serious magnetic hysteresis. Large coercive force will cause low Signal-to-Noise and even low sensitivity. To overcome the large coercive force, additional magnetic layers, such as shields, hard magnetic bias, or current bias layers are commonly employed. However, either the shield or bias layers will cause a reduction in sensor sensitivity, in addition to the process complexity and extra cost incurred.

Therefore, an improved alternative is to align multiple isolated magnetic sensor elements in series. FIG. 1 shows the schematic illustration of the existing magnetic sensor. The magnetic sensor 1 includes a magnetic sensor film 11 cutting into a plurality of isolated magnetic sensor elements 111 arrange in row, and a plurality of conductive lead layers 12 with each conductive lead layer 12 being connected two adjacent magnetic sensor elements 111. The magnetic sensor 1 further includes two electric pads 14 and a plurality of cutouts 13. As a plurality of cutouts 13 is designed to isolate the magnetic sensor elements 111 which are connected with each other through the conductive lead layer 12 arranged therebetween, the serious magnetic hysteresis of the magnetic sensor 1 is advance. Nevertheless, in case of isolated sensor elements in series, individual sensor elements may subject to changes in shape anisotropy once the long and short axis direction swaps. Also, the stress anisotropy may change if film stress releases due to dry etching or wet etching, and the etching process of the magnetic sensor have adverse impact on coercive force and anisotropy field or sensitivity. Further, the isolated arrangement of the magnetic sensor elements cripples the antistatic ability and reliability performance of the magnetic sensor. FIG. 2 shows the big coercive force of the magnetic sensor of the prior art.

Accordingly, a need has arisen for providing an improved magnetic sensor with shunting layers to reduce the coercive force thereof, and a manufacturing method for the magnetic sensor, to overcome the above-mentioned drawbacks.

### SUMMARY OF THE INVENTION

One objective of the present invention is to provide a magnetic sensor, with a plurality of shunting layers forming on a magnetic sensor bar. Owing to any part of the magnetic sensor bar which is laminated with the shunting layers becomes inactive, and the magnetic sensor bar has an integral structure, magnetic sensor has low coercive force and high sensitivity performance, and high antistatic ability and better reliability thereof are obtained.

Another objective of the present invention is to provide a manufacturing method of magnetic sensor, with the magnetic sensor having a plurality of shunting layers forming on a magnetic sensor bar. Owing to any part of the magnetic sensor bar which is laminated with the shunting layers becomes inactive, and the magnetic sensor bar has an integral structure, magnetic sensor has low coercive force and high sensitivity performance, and high antistatic ability and better reliability thereof are obtained.

To achieve the above-mentioned objects, the present invention provides a magnetic sensor with shunting layers, and the magnetic sensor includes a magnetic sensor bar which has an integral structure; and a plurality of shunting layers whose resistivity is lower than the magnetic sensor bar, respectively forming on the magnetic sensor bar in length direction without any physical separation therebetween, with spaces between every two adjacent shunting layers; and two electrode pads respectively forming on two ends of the magnetic sensor bar.

As an embodiment of the present invention, the ratio of the width of magnetic sensor bar to the space between any two adjacent shunting layers is within the range of 0.8-1.2.

Preferably, the width of magnetic sensor bar is identical to the space between any two adjacent shunting layers. As such, low coercive force could be obtained to achieve high sensitivity performance of the magnetic sensor.

As an embodiment of the present invention, the shunting layer is a ring enclosing the magnetic sensor bar perpendicular to its length direction.

As another embodiment of the present invention, the shunting layer has a shape of square, rectangular or oval to laminate on the magnetic sensor bar.

As another embodiment of the present invention, the material of the shunting layer is composed of gold, copper, silver, or other low resistivity metals.

As yet another embodiment of the present invention, the magnetic sensor bar is Anisotropic Magneto Resistance, Giant Magneto Resistance or Tunneling Magneto Resistance.

As yet another embodiment of the present invention, the magnetic sensor further comprises a plurality of seedlayers correspondingly sandwiched between the shunting layers and the magnetic sensor bar, so as to achieve good adhesion therebetween.

Preferably, the seedlayer is composed of chromium, titanium or tantalum.

As still another embodiment of the present invention, the magnetic sensor further comprises an undercoat layer composed of insulating material on which the magnetic sensor bar formed, and a substrate with the undercoat layer formed thereon.

Preferably, the undercoat layer is consisted of alumina or silicon oxide, and the substrate is consisted of silicon, magnesium oxide, sapphire, AlTiC or glass.

As still another embodiment of the present invention, the magnetic sensor is covered with a protection layer, which is composed of alumina, silicon oxide, ink or polyimide.

To achieve the above-mentioned objects, the present invention also provides a manufacturing method of magnetic sensor, which includes the following steps: providing a substrate; depositing a undercoat film on the substrate, depositing a magnetic sensor film on the undercoat or directly on substrate which already has an insulating surface layer, and etching the magnetic sensor film into a plurality of magnetic sensor bars, each of which has an integral structure; depositing a shunting film without any physical separation therebetween on the magnetic sensor bar, and patterning the shunting film into a plurality of shunting layers, whose resistivity is lower than the magnetic sensor bar, formed in length direction of the magnetic sensor, with spaces between every two adjacent shunting layers; and depositing two electrode pads respectively on two ends of the magnetic sensor bar.

As an embodiment of the present invention, the ratio of the width of magnetic sensor bar to the space between any two adjacent shunting layers is within the range of 0.8-1.2.

Preferably, the width of magnetic sensor bar is identical to the space between any two adjacent shunting layers. As such, low coercive force could be obtained to achieve high sensitivity performance of the magnetic sensor.

As an embodiment of the present invention, patterning of the magnetic sensor film is carried out by dry or wet etching with photo mask.

As an embodiment of the present invention, patterning of the shunting film is carried out by directly depositing into photo patterns or after deposition the dry or wet etching.

As another embodiment of the present invention, the shunting layer is a ring enclosing the magnetic sensor bar perpendicular to its length direction.

As another embodiment of the present invention, the shunting layer has a shape of square, rectangular or oval to laminate on the magnetic sensor bar.

As yet another embodiment of the present invention, the material of the shunting layer is composed of gold, copper, silver, or other low resistivity metals.

As yet another embodiment of the present invention, the magnetic sensor bar is Anisotropic Magneto Resistance, Giant Magneto Resistance, or Tunneling Magneto Resistance.

As still another embodiment of the present invention, the magnetic sensor further comprises a plurality of seedlayers correspondingly sandwiched between the shunting layers and the magnetic sensor bar, so as to achieve good adhesion therebetween.

Preferably, the seedlayer is composed of chromium, titanium or tantalum.

As still another embodiment of the present invention, the undercoat layer is consisted of alumina or silicon oxide, and the substrate is consisted of silicon, magnesium oxide, sapphire, AlTiC or glass.

As still another embodiment of the present invention, the manufacturing method further comprises a step of depositing an undercoat layer composed of insulating material on the substrate, with the magnetic sensor film laminated thereon.

As still another embodiment of the present invention, the manufacturing method further comprises a step of covering the magnetic sensor with a protection layer, which is composed of alumina, silicon oxide, ink or polyimide.

To achieve the above-mentioned objects, the present invention also provides manufacturing method of magnetic sensor, and the method comprises the following steps: providing a substrate; depositing a magnetic sensor film on the substrate, and etching the magnetic sensor film into a plurality of magnetic sensor bars, each of which has an integral structure; arranging a photo mask directly on the magnetic sensor bar with a plurality of specific areas of the photo mask exposing the magnetic sensor bar, then depositing a shunting film onto and cover the whole the photo mask, whereby a plurality of shunting layers are formed on the magnetic sensor bar without any physical separation therebetween via said specific areas of the photo mask, and patterning the shunting film into a plurality of shunting layers, whose resistivity is lower than the magnetic sensor bar, formed in length direction of the magnetic sensor, with spaces between every two adjacent shunting layers; and depositing two electrode pads respectively on two ends of the magnetic sensor bar.

In comparison with the prior art, the magnetic sensor has a magnetic sensor bar has an integral structure, and a plurality of shunting layers forming on a magnetic sensor bar. Owing to any part of the magnetic sensor bar which is laminated with the shunting layers becomes inactive, and the magnetic sensor bar has an integral structure, magnetic sensor have low coercive force and high sensitivity performance, and high antistatic ability and better reliability thereof are obtained.

Other aspects, features, and advantages of this invention will become apparent from the following detailed description when taken in conjunction with the accompanying drawings, which are a part of this disclosure and which illustrate, by way of example, principles of this invention.

### BRIEF DESCRIPTION OF THE DRAWINGS

The accompanying drawings facilitate an understanding of the various embodiments of this invention. In such drawings:

FIG. 1 is a schematic illustration of the existing magnetic sensor;

FIG. 2 is a explanatory drawing illustrating the coercive force magnetic sensor of the prior art;

FIG. 3 is a schematic illustration of the magnetic sensor according to the embodiment of the present invention;

FIG. 4 is a schematic illustration of the magnetic sensor according to another the embodiment of the present invention;

FIG. 5 is a schematic illustration of the magnetic sensor according to another the embodiment of the present invention;

FIG. 6 is a explanatory drawing illustrating the coercive force of the magnetic sensor according to another the embodiment of the present invention; and

FIG. 7 is a flow chart illustrating the manufacturing method of magnetic sensor according to another the embodiment of the present invention.

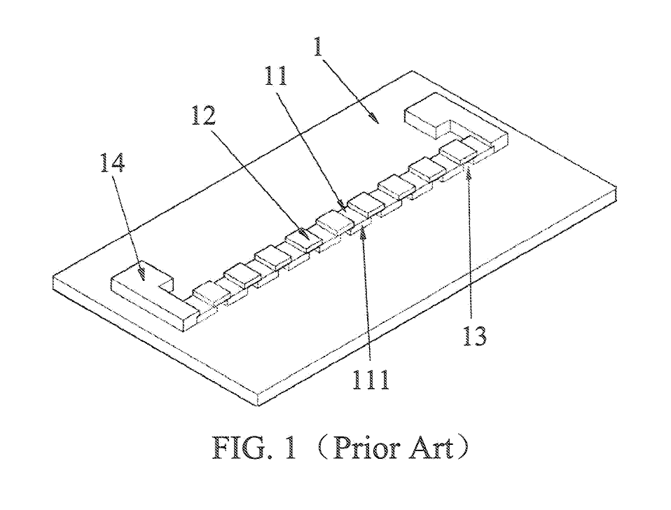

### DETAILED DESCRIPTION OF ILLUSTRATED EMBODIMENTS

Various preferred embodiments of the invention will now be described with reference to the figures, wherein like reference numerals designate similar parts throughout the various views. According to the present invention, the magnetic sensor is used to sense the spatially distributed magnetic signals.

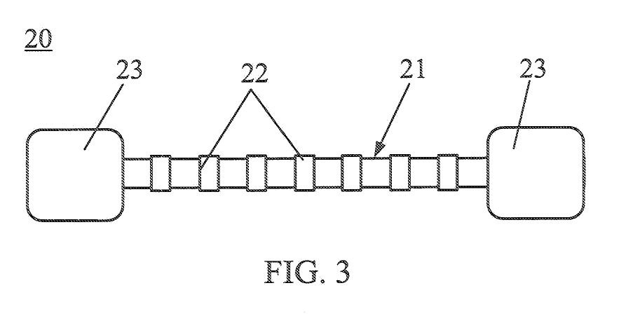

Referring to FIG. 3, the magnetic sensor 20 includes a magnetic sensor bar 21, a plurality of shunting layers 22 and electrode pads 23. The magnetic sensor bar 21 has an integral structure, without any physically separating into a number of portions. The magnetic sensor bar 21 is characteristic of Anisotropic Magneto Resistance, Giant Magneto Resistance or Tunneling Magneto Resistance. A plurality of said shunting layers 22 are respectively forming on the magnetic sensor bar 21 in length direction without any physical separation therebetween, with spaces between every two adjacent shunting layers 22. In this embodiment, the shunting layers 22 are formed on the magnetic sensor bar 21 without any other material arranged therebetween. The shunting layer 22 is made of low resistivity material, which is lower than that of the magnetic sensor bar 21, and the shunting layer 22 is laminated on and electrically connected to the magnetic sensor bar 21. Preferably, the spaces between every two adjacent shunting layers 22 are identical to each other. The material of the shunting layer 22 is composed of gold, copper or silver. It should be note that the material of the shunting layer is employed for reference to the material of the magnetic sensor bar. Two electrode pads 23 are respectively forming on two ends of the magnetic sensor bar 21 along its length direction. And, the material of the electrode pad 23 is gold or copper. The electrode pad 23 is employed to electrically connect the magnetic sensor to the external device.

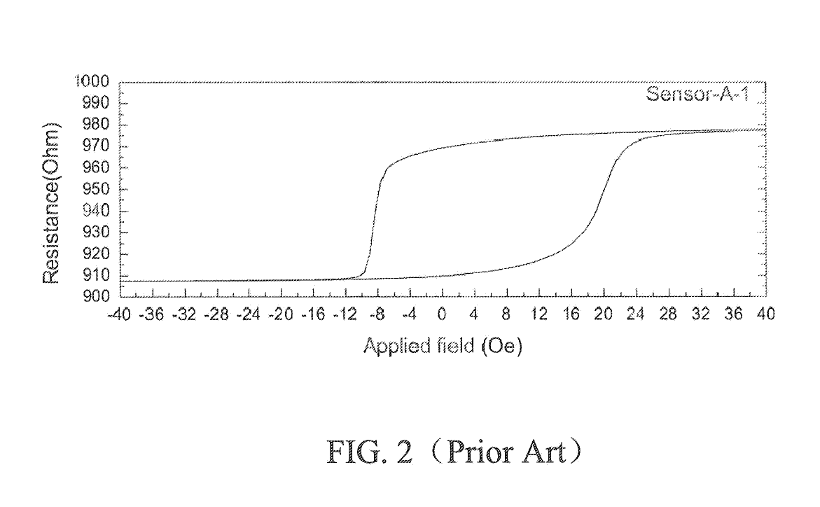

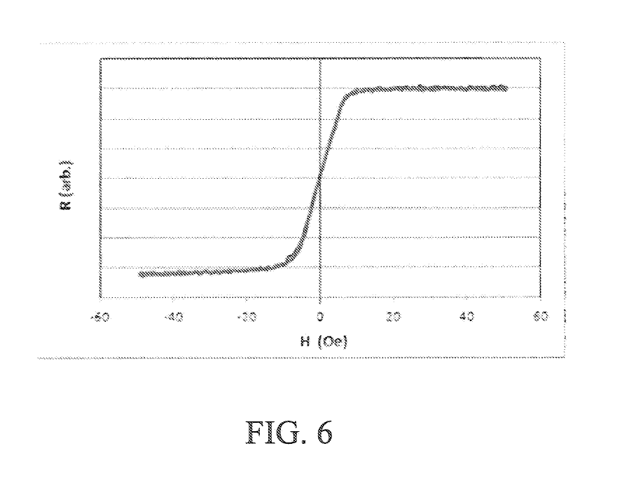

Referring to FIG. 3, preferably, the ratio of the width of magnetic sensor bar to the space between any two adjacent shunting layers is within the range of 0.8-1.2, as such, the low coercive force is achieved. In this embodiment, the width of magnetic sensor bar is identical to the space between any two adjacent shunting layers; accordingly, low coercive force could be obtained to achieve high sensitivity performance of the magnetic sensor. Referring to FIG. 6, comparing to the coercive force of the magnetic sensor shown in FIG. 2, because the magnetic sensor bar has an integral structure, multiple elements of the magnetic sensor bar is separated via the shunting layers formed thereon, and especially the width of magnetic sensor bar is identical to the space between any two adjacent shunting layers, smaller coercive force which is lower than 0.5 Oe of the magnetic sensor according to the present invention is obtained shown in FIG. 6. The shunting layer 22 is a ring shape to enclose the magnetic sensor bar 21 along the direction perpendicular to the length direction of the magnetic sensor bar 21. In this embodiment, the shunting layer 22 is laminated on the magnetic bar 21 without any physical separation therebetween, that is to say, there is nothing to arrange between the shunting layer 22 and the magnetic bar 21, so that good electrical connection and connection stability therebetween is obtained. In other embodiments of the present invention, the magnetic sensor could include a plurality of seedlayers, each of which is correspondingly sandwiched between every shunting layer and the magnetic sensor bar, so as to achieve good adhesion therebetween. The seedlayer is composed of chromium, titanium or tantalum.

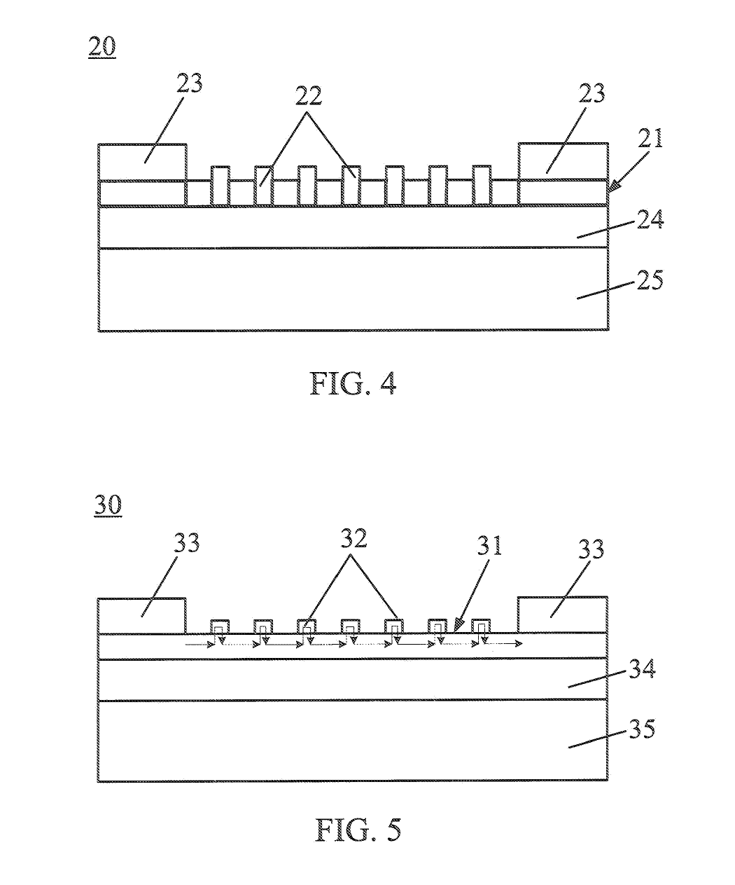

Referring to FIGS. 3-4, in this embodiment, the magnetic sensor bar 20 further includes an undercoat layer 24 and a substrate 25. The undercoat layer 24 is deposited on the substrate 25 or formed by an oxidation layer at substrate surface, and the magnetic sensor bar 21 is deposited on the undercoat layer 24. The undercoat layer 24 is composed of insulating material, such as alumina or silicon oxide, and the substrate is consisted of silicon, magnesium oxide, sapphire, AlTiC or glass material. Preferably, the magnetic sensor 20 is covered with a protection layer(not shown), which is composed of alumina, silicon oxide, ink or polyimide.

FIG. 5 illustrates another embodiment of the present invention. Referring to FIG. 5, the magnetic sensor 30 includes a magnetic sensor bar 31, a plurality of shunting layer 32, electrode pads 33, an undercoat layer 34, and a substrate 35. The structure of the magnetic sensor 30 is similar to the magnetic sensor 20 shown in FIG. 3, while the difference lies in the shape of the shunting layer 32. In this embodiment, the shunting layer 32 is characteristic of square shape, to laminate on the magnetic sensor bar 31, without enclosing the magnetic sensor bar 31. In other embodiments, the shape of the shunting layer could be rectangular or oval, etc, which depends on the actual conditions.

Referring to FIGS. 3 and 6, a plurality of shunting layers 22 is laminated on the magnetic sensor bar 21. When the magnetic sensor 20 is applied with predetermined working current to operate, the working current goes through the magnetic sensor 20 via the magnetic sensor bar 21. As the arrows shows in FIG. 5, since the resistivity of the shunting layer 22 is lower than that of the magnetic sensor bar 21, the working current goes through the magnetic sensor bar 21 in the event that some parts of the magnetic sensor bar 21 is not covered with the shunting layer 22; while the working current goes through the shunting layer 22 in the event that some parts of the magnetic sensor bar 21 is covered with the shunting layers 22. Accordingly, the parts of the magnetic sensor bar 21 which are covered with the shunting layers 22 are out of operating when the magnetic sensor 20 is operated. Therefore, the magnetic sensor bar 21 is separated into multiple isolated elements electrically connected in series throng the shunting layers 22 in magnetic level, it accomplishes the separation needed to obtain equal demagnetization factors for long and short axis of the magnetic sensor bar, and lower coercive force and high sensitivity performance of the magnetic sensor bar is obtained. The embodiments shown in FIG. 5 are also applicable to the above advantage.

Furthermore, since the magnetic sensor bar according to the embodiments of the present invention is separated into multiple isolated elements in magnetic level via the shunting layers, without any physical breaking and removal therefore, hence, the magnetic sensor bar has an integral structure. No physical separation is occurred in the longitudinal direction of the magnetic sensor and much better integrity of the anti-ferromagnetic layer is obtained, consequently, no changes in magnetic shape and stress anisotropy are occurred to the magnetic sensor, so that high antistatic ability and better reliability of the magnetic sensor are obtained. Moreover, no changes in magnetic shape and stress anisotropy is occurred, thus, small coercive force and high sensitivity of the magnetic sensor is achieved.

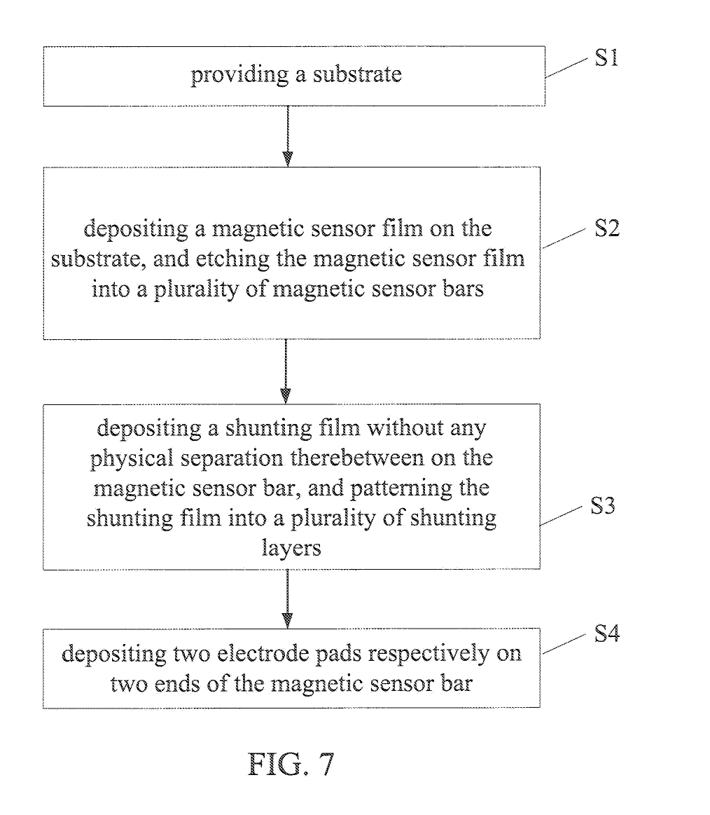

The present invention is also provided with a method for manufacturing the magnetic sensor according to the above-mentioned embodiments. FIG. 7 illustrates a flow chart of the manufacturing method of the magnetic sensor according to the present invention. Referring to FIG. 7, the manufacturing method generally includes the follow steps:

In step one as marks S1 in FIG. 7, a substrate is provided, whose chief constituent is Si, MgO, sapphire, AlTiC or glass, etc. And in this embodiment, the substrate is made of Si.

In step two as marks S2 in FIG. 7, a magnetic sensor film is deposited on the substrate, and the magnetic sensor film is patterned into a plurality of magnetic sensor bars by dry or wet etching on photo mask method, each magnetic sensor bar has an integral structure;

In step three as marks S3 in FIG. 7, a shunting film is deposited on the magnetic sensor bar without any other material arranged therebetween, and the shunting film is patterned into a plurality of shunting layers by directly depositing into photo pattern, or after shunting film deposition, dry or wet etching is carried out with the guide of photo mask. The resistivity of the shunting layer is lower than the magnetic sensor bar, and the shunting layers are formed in length direction of the magnetic sensor, with spaces between every two adjacent shunting patterns layers.

In step four as marks S4 in FIG. 7, two electrode pads are deposited respectively on two ends of the magnetic sensor bar.

It should be note that, in other embodiment of the present invention, the magnetic sensor film could be etched by other dry or wet etching methods such as ion milling, RIE, wet chemical etching, etc; and the shunting film could be etched by other dry or wet etching methods such as ion milling, RIE, wet chemical etching, etc.

Preferably, the above method for manufacturing the magnetic sensor further comprises sandwiching a plurality of seedlayers correspondingly between the shunting layers and the magnetic sensor bar, so as to achieve good adhesion therebetween. And the seedlayer is composed of chromium, titanium or tantalum.

Preferably, the manufacturing method further comprises a step of depositing an undercoat layer composed of insulating material on the substrate, with the magnetic sensor film laminated thereon. And the undercoat layer is consisted of alumina or silicon oxide.

In other embodiment of the present invention, the manufacturing method further comprises a step of covering the magnetic sensor with a protection layer, which is composed of alumina, silicon oxide, ink or polyimide.

Another embodiment of the present invention also provides a manufacturing method of magnetic sensor, and the method comprises the following steps: providing a substrate; depositing a magnetic sensor film on the substrate, and etching the magnetic sensor film into a plurality of magnetic sensor bars, each of which has an integral structure; arranging a photo mask directly on the magnetic sensor bar with a plurality of specific areas of the photo mask exposing the magnetic sensor bar, then depositing a shunting film onto the photo mask and cover the whole the photo mask, whereby after the photo mask is removed, a plurality of shunting layers are formed on the magnetic sensor bar without any physical separation therebetween via said specific areas of the photo mask, and patterning the shunting film into a plurality of shunting layers, whose resistivity is lower than the magnetic sensor bar, formed in length direction of the magnetic sensor, with spaces between every two adjacent shunting layers; and depositing two electrode pads respectively on two ends of the magnetic sensor bar.

While the invention has been described in connection with what are presently considered to be the most practical and preferred embodiments, it is to be understood that the invention is not to be limited to the disclosed embodiments, but on the contrary, is intended to cover various modifications and equivalent arrangements included within the spirit and scope of the invention.

What is claimed is:

1. A magnetic sensor with shunting layers, comprising:
a magnetic sensor bar having an integral structure;
a plurality of shunting layers, whose resistivity is lower than the magnetic sensor bar, respectively forming on the magnetic sensor bar in length direction without any physical separation therebetween, and with spaces between every two adjacent shunting layers; and
two electrode pads respectively forming on two ends of the magnetic sensor bar.

2. The magnetic sensor according to claim 1, wherein the ratio of the width of magnetic sensor bar to the space between any two adjacent shunting layers is within the range of 0.8-1.2.

3. The magnetic sensor according to claim 1, wherein the width of magnetic sensor bar is identical to the space between any two adjacent shunting layers.

4. The magnetic sensor according to claim 1, wherein the shunting layer is a ring enclosing the magnetic sensor bar perpendicular to its length direction.

5. The magnetic sensor according to claim 1, wherein the shunting layer has a shape of square, rectangular or oval to laminate on the magnetic sensor bar.

6. The magnetic sensor according to claim 1, wherein the material of the shunting layer is composed of gold, copper or silver.

7. The magnetic sensor according to claim 1, wherein the magnetic sensor bar is Anisotropic Magneto Resistance, Giant Magneto Resistance or Tunneling Magneto Resistance.

8. The magnetic sensor according to claim 1, wherein the magnetic sensor further comprises a plurality of seedlayers correspondingly sandwiched between the shunting layers and the magnetic sensor bar, so as to achieve good adhesion therebetween.

9. The magnetic sensor according to claim 8, wherein the seedlayer is composed of chromium, titanium or tantalum.

10. The magnetic sensor according to claim 1, wherein the magnetic sensor further comprises an undercoat layer composed of insulating material on which the magnetic sensor bar formed, and a substrate with the undercoat layer formed thereon.

11. The magnetic sensor according to claim 10, wherein the undercoat layer is consisted of alumina or silicon oxide, and the substrate is consisted of silicon, magnesium oxide, sapphire, AlTiC or glass.

12. The magnetic sensor according to claim 1, wherein the magnetic sensor is covered with a protection layer, which is composed of alumina, silicon oxide, ink or polyimide.

13. A manufacturing method of magnetic sensor, comprising:
providing a substrate;
depositing a magnetic sensor film on the substrate, and etching the magnetic sensor film into a plurality of magnetic sensor bars, each of which has an integral structure;
depositing a shunting film on the magnetic sensor bar without any physical separation therebetween, and patterning the shunting film into a plurality of shunting layers, whose resistivity is lower than the magnetic sensor bar, formed in length direction of the magnetic sensor, with spaces between every two adjacent shunting layers; and
depositing two electrode pads respectively on two ends of the magnetic sensor bar.

14. The manufacturing method according to claim 13, wherein the ratio of the width of magnetic sensor bar to the space between any two adjacent shunting layers is within the range of 0.8-1.2.

15. The manufacturing method according to claim 13, wherein the width of magnetic sensor bar is identical to the space between any two adjacent shunting layers.

16. The manufacturing method according to claim 13, wherein etching the magnetic sensor film is carried out by dry or wet etching.

17. The manufacturing method according to claim 13, wherein patterning the shunting film is carried out by dry or wet etching the shunting film with photo mask.

18. The manufacturing method according to claim 13, wherein the shunting layer is a ring enclosing the magnetic sensor bar perpendicular to its length direction.

19. The manufacturing method according to claim 13, wherein the shunting layer has a shape of square, rectangular or oval to laminate on the magnetic sensor bar.

20. The manufacturing method according to claim 13, wherein the material of the shunting layer is composed of gold, copper or silver.

21. The manufacturing method according to claim 13, wherein the magnetic sensor bar is Anisotropic Magneto Resistance, Giant Magneto Resistance, or Tunneling Magneto Resistance.

22. The manufacturing method according to claim 13, wherein the magnetic sensor further comprises a plurality of seedlayers correspondingly sandwiched between the shunting layers and the magnetic sensor bar, so as to achieve good adhesion therebetween.

23. The manufacturing method according to claim 22, wherein the seedlayer is composed of chromium, titanium or tantalum.

24. The manufacturing method according to claim 13, wherein the manufacturing method further comprises a step of depositing an undercoat layer composed of insulating material on the substrate, with the magnetic sensor film laminated thereon.

25. The manufacturing method according to claim 24, wherein the undercoat layer is consisted of alumina or silicon oxide, and the substrate is consisted of silicon, magnesium oxide, sapphire, AlTiC or glass.

26. The manufacturing method according to claim 13, wherein the manufacturing method further comprises a step of covering the magnetic sensor with a protection layer, which is composed of alumina, silicon oxide, ink or polyimide.

27. A manufacturing method of magnetic sensor, comprising:
providing a substrate;
depositing a magnetic sensor film on the substrate, and etching the magnetic sensor film into a plurality of magnetic sensor bars, each of which has an integral structure;
arranging a photo mask directly on the magnetic sensor bar with a plurality of specific areas of the photo mask exposing the magnetic sensor bar, then depositing a shunting film onto and cover the whole the photo mask, whereby a plurality of shunting layers are formed on the magnetic sensor bar without any physical separation therebetween via said specific areas of the photo mask, whose resistivity is lower than the magnetic sensor bar, formed in length direction of the magnetic sensor, with spaces between every two adjacent shunting layers; and
depositing two electrode pads respectively on two ends of the magnetic sensor bar.

28. The manufacturing method according to claim 27, wherein the ratio of the width of magnetic sensor bar to the space between any two adjacent shunting layers is within the range of 0.8-1.2.

29. The manufacturing method according to claim 27, wherein the width of magnetic sensor bar is identical to the space between any two adjacent shunting layers.
